(19) United States
(12) Patent Application Publication
(10) Pub. No.: US 2019/0385657 A1
(43) Pub. Date: Dec. 19, 2019

(54) HIGH DENSITY NEGATIVE DIFFERENTIAL RESISTANCE BASED MEMORY

(71) Applicant: Intel Corporation, Santa Clara, CA (US)

(72) Inventors: Charles Augustine, Portland, OR (US); Charles Kuo, Hillsboro, OR (US); Benjamin Chu-kung, Portland, OR (US); Muhammad Khellah, Tigard, OR (US)

(73) Assignee: Intel Corporation, Santa Clara, CA (US)

(21) Appl. No.: 16/012,634

(22) Filed: Jun. 19, 2018

(51) Int. Cl. G11C 11/38; G11C 11/412; G11C 11/419; H01L 27/11

(52) U.S. Cl. CPC G11C 11/38; G11C 11/412; G11C 11/418; H01L 27/1104; H01L 27/11; G11C 11/419

(57) ABSTRACT

An apparatus is provided which comprises: a storage node; a first device coupled to the storage node; a second device coupled to a first reference and the storage node, wherein the second device has negative differential resistance (NDR); a third device coupled to a second reference and the storage node, wherein the third device has NDR; and a circuitry for reading data, the circuitry coupled to the storage node and the first, second, and third devices, wherein the first, second, and third devices, and the circuitry are positioned in a backend-of-line (BEOL) of a die.

### BACKGROUND

Dense and high performance embedded memory is an essential ingredient for high performance Central Processing Units (CPUs), Graphics Processing Units (GPUs), and System-on-Chips (SoCs). Static Random Access Memory (SRAM) is a commonly used memory, but it is not scaling well to low power supply voltages (e.g., less than 1 Volt (V)) at advanced process nodes. For example, six transistor (6T) SRAM is becoming unstable and slow at low voltages (e.g., less than 1 V) and also need a higher minimum operating voltage (Vmin). While 8T SRAM improves speed over a 6T SRAM, it does so at the cost of area.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a high-level circuit of a negative differential resistance (NDR) device based memory bit-cell, according to one embodiment of the disclosure.

FIGS. 2A-C illustrate plots showing I-V characteristics of an NDR diode and associated circuit.

FIGS. 2D-E illustrates plots showing I-V characteristics of the NDR diode and associated circuit for different power supply voltages, in accordance with some embodiments.

FIG. 3 illustrates a schematic of an NDR memory cell with separate read and write ports, in accordance with some embodiments of the disclosure.

FIG. 4A illustrates a schematic of an NDR memory cell with five transistors, in accordance with some embodiments.

FIG. 4B illustrates a plot showing improvement in data retention by the NDR memory of FIG. 4A relative to a typical NDR memory, in accordance with some embodiments of the disclosure.

FIG. 5A illustrates a plot showing rise and fall write delays of the NDR memory relative to a typical NDR memory, in accordance with some embodiments.

FIG. 5B illustrates a plot showing the effect of write word-line (WWL) boosting for the NDR memory compared to a typical NDR memory, in accordance with some embodiments.

FIG. 5C illustrates a plot showing improvement in read current with read word-line (RWL) boasting, in accordance with some embodiments.

FIG. 6A illustrates a schematic of an NDR memory cell with one transistor and a field programmable grid array (FPGA), in accordance with some embodiments of the disclosure.

FIG. 6B illustrates a schematic of an NDR memory cell with one transistor and a FPGA, in accordance with some other embodiments of the disclosure.

FIG. 7 illustrates a schematic of an NDR memory cell with one transistor and capacitor, in accordance with some embodiments of the disclosure.

FIG. 8 illustrates a schematic of an NDR memory cell with one transistor and capacitor, in accordance with some embodiments of the disclosure.

FIGS. 9A-D illustrate single NDR device based memory bit-cells with p-type transistors and a capacitor, according to one embodiment of the disclosure.

FIG. 10 illustrates a three-dimensional (3D) architecture of an NDR based memory, in accordance with some embodiments.

FIG. 11 illustrates a smart device or a computer system or a SoC (System-on-Chip) with NDR device based memory, according to one embodiment of the disclosure.

### DETAILED DESCRIPTION

Negative Differential Resistance SRAM (NDR-SRAM) can substitute for 6T Complementary Metal Oxide Semiconductor (CMOS) SRAM cell due to lower number of transistors (e.g., 3T vs 6T) resulting in smaller area and lower leakage power, and lower minimum operating supply VCC_{MIN} due to decoupled read and write paths. However, due to parametric process variation, feedback in NDR-SRAM can be weakened resulting in data retention failure.

Some embodiments describe a memory bit-cell which addresses the retention failure condition on the storage node of current NDR-SRAM bit-cells by using a Schmitt triggered device. In NDR-SRAM, state storing element is a three terminal Schmitt trigger device with two NDR device connected in series. In some embodiments, Schmitt trigger device can be manufactured as a single monolithic structure with small area. Here, the storage node is used for both reading and writing. Two other terminals of the device are connected to first reference (Vdd) and second reference (e.g., Vss), respectively.

In some embodiments, the transistors and/or diodes of the NDR-SRAM comprise indium gallium, zinc oxide (IGZO) material that allows for fabricating the NDR-SRAM bit-cell on a Backend-of-Line (BOEL) portion of a die. As such, a three-dimensional (3D) memory architecture is formed where the NDR-SRAM bit-cell are fabricated in the BOEL portion of the die while other memory circuits such as column decoders, row/column multiplexers, sense amplifiers, etc., can be fabricated in CMOS technology on the Frontend-of-line (FOEL) portion of the die, in accordance with various embodiments. In some embodiments, memory circuits such as column decoders, row/column multiplexers, sense amplifiers, etc. are also fabricated on the BEOL of the die and comprise indium gallium, zinc oxide (IGZO) material. In some embodiments, the read transistors of the NDR-SRAM are replaced with a 3D capacitor which is fabricated in the BEOL of the die. The 3D NDR-SRAM of various embodiments results in similar performance as a typical NDR-SRAM but with much higher density, saving area and cost. Other technical effects will be evident from the various embodiments and figures.

Some embodiments describe a memory bit-cell which comprises: a storage node; a device coupled to the storage node; a first negative differential resistance (NDR) device coupled to a first reference and the storage node; a second NDR device coupled to a second reference and the storage node; and a circuitry for reading data, wherein the circuitry is coupled to the storage node, device, and first and second NDR devices. In some embodiments, the circuitry comprises a second device having a gate terminal coupled to the storage node, and a source terminal coupled to the second reference. In some embodiments, the circuitry comprises a third device having a gate terminal coupled to a read word-line (RWL), a source/drain terminal coupled to a read bit-line (RBL), and a drain/source terminal coupled to the second device. In some embodiments, the first reference is a power supply node (Vdd) while the second reference is a ground supply node (Vss). The memory bit-cell of various embodiments is smaller in size (e.g., x and y layout dimensions are smaller) compared to a traditional six transistor (6T) static random access memory (SRAM) bit-cell. For example, the layout of a memory bit-cell of various embodiments is three times smaller than a 6T SRAM bit-cell layout.

In some embodiments, the first and second NDR devices provide Schmitt Trigger mechanism. In some embodiments, the feedback provided by Schmitt trigger NDR devices can be made stronger by incorporating two additional devices in series with the Schmitt trigger NDR devices. This updated stronger Schmitt trigger structure can be used for improving read operation and for also improving retention V_{MIN}, which is the minimum supply voltage for an operational memory device. Note, supply voltage below V_{MIN} results in date on the storage node being lost or corrupted. In some embodiments, the additional feedback in the memory cell improves stability of the storage cell for storing either ‘0’ or ‘1’. In some embodiments, the Schmitt trigger mechanism or circuitry uses two additional transistors (e.g., one n-type and one p-type) which can be realized using conventional transistors in front-end-of-line (FEOL) or IGZO transistors in backend of line (BEOL) depending on the implementation. In some embodiments, the device has a gate terminal coupled to a write word-line (WWL). In some embodiments, the device is coupled to a write bit-line (WBL). In some embodiments, the device is one of: a p-type transistor; or an n-type transistor. In some embodiments, the device comprises thin film transistor (TFT). In some embodiments, the circuit comprises a field programmable grid array (FPGA). In some embodiments, the NDR memory bit-cell is positioned in a backend of line (BEOL) of a die, wherein the other memory circuitries such as column/row decoders, sense amplifiers, write drivers, etc. are positioned in a frontend of line (FEOL) of the die.

Here, the term “backend” or BEOL generally refers to a section of a die which is opposite of a “frontend” and where an IC (integrated circuit) package couples to IC die bumps. For example, high level metal layers (e.g., metal layer 6 and above in a ten metal stack die) and corresponding vias that are closer to a die package are considered part of the backend of the die. The BEOL is the portion of IC fabrication where individual semiconductor devices (whether embedded memory or logic transistors) are interconnected to one another with electrically conductive features such as metal interconnect traces (lines) within a given metallization level and metal-filled conductive vias between multiple metallization levels. These conductive interconnects are embedded in a dielectric material so that the memory device is a monolithic integrated circuit. Conversely, the term “frontend” or FEOL generally refers to a section of the die that includes the traditional active region (e.g., where transistors (e.g., BJT, MOS) are fabricated) and low level metal layers and corresponding vias that are closer to the active region (e.g., metal layer 5 (M5) and below in a ten metal stack die example).

In the following description, numerous details are discussed to provide a more thorough explanation of the embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front,” “back,” “top,” “bottom,” “over,” “under,” and the like in the description and in the claims, if any, are used for descriptive purposes and not necessarily for describing permanent relative positions. The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material “on” a second material is in direct contact with that second material. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

It is pointed out that those elements of a figure having the same reference numbers (or names) as the elements of any other figure can operate or function in any manner similar to that described, but are not limited to such.

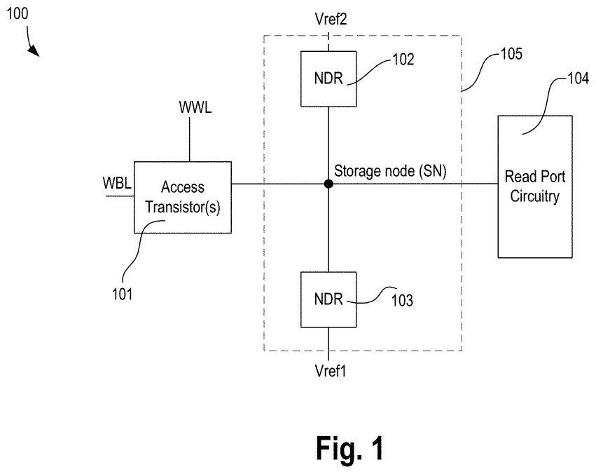

FIG. 1 illustrates a high-level circuit 100 of an NDR device based memory bit-cell, according to one embodiment of the disclosure. In some embodiments, circuit 100 comprises one or more Transistors 101 (e.g., access device), first and second NDR devices 102 and 103, respectively, Storage node (SN), read port circuitry 104, and Schmitt Triggered mechanism 105 encompassing first and second NDR devices 102 and 103.

A device with NDR characteristic exhibits higher conductance at low voltages than at high voltages. A variety of materials and device structures exhibit an NDR characteristic including: Esaki diodes, RTD, TFETs. The ratio of the maximum current at low voltage to the minimum current at higher voltage is called the peak-to-valley ratio (PVR), and the voltages at which these current levels are observed are known as the peak voltage and valley voltage, respectively. NDR devices have a general limitation of low peak-to-valley ratios and low peak currents. The bit-cells of some embodiments described here work with the low peak currents (e.g., less than 0.1 nA (nano-Ampere)). The bit-cells would work with NDR devices with higher peak current levels as well.

When the two tunneling NDR devices 102 and 103 are coupled in series, the resulting combination is a circuit element called a twin. The twin forms a bi-stable memory element with the middle or common node as SN. In some embodiments, first NDR device 102 is coupled to a reference supply Vref2 (e.g., power supply Vdd) and SN. In some embodiments, second NDR device 103 is coupled to another reference supply Vref1 (e.g., ground supply Vss) and SN. In some embodiments, when the voltage on SN is at a high voltage (e.g., close to Vdd), first NDR device 102 (also referred to as the pull-up NDR device) sources current more strongly than the second NDR device 103 (also referred to as the pull-down NDR device) can sink it, thus keeping the voltage on SN high. Conversely, when the voltage on SN is at a low voltage pull-down second NDR device 103 sinks current more strongly and SN can be held at a low voltage.

Here, first and second NDR devices 102 and 103 are represented as two terminal devices but in general devices 102 and 103 may have two or more physical terminals with an NDR characteristic between at least two terminals. In various embodiments, hysteresis behavior of Schmitt Trigger devices are used for implementing the NDR behavior as illustrated by identifier 105. The hysteresis behavior of Schmitt Trigger devices allows for an alternative implementation than traditional NDR devices.

In some embodiments, the one or more Transistors 101 (also referred here as access transistor(s)) are a single n-type or p-type transistor. In some embodiments, thin film transistors (TFTs) may be used for implementing the one or more Transistors 101. Thin-film transistors (TFTs) are a class of field-effect transistors (FETs) in which the channel material is a deposited thin film rather than a monocrystalline material. A common application of TFT technology is liquid crystal displays (LCDs), but TFTs are also advantageous in other applications as the thin film deposition processes employed in TFT fabrication can be relatively low (e.g., below 450° C.), allowing TFTs to be inserted within layers of interconnect metallization of the type that is typically formed only after higher-temperature processing is completed in conventional silicon MOSFET fabrication technology. TFTs can be fabricated using a wide variety of semiconductor materials, such as silicon, germanium, silicon-germanium, as well as various oxide semiconductors (a.k.a. semiconducting oxides) including metal oxides such as indium gallium zinc oxide (IGZO), indium zinc oxide (IZO), and the like.

In some embodiments, the gate terminal of the one or more Transistors 101 is coupled to WWL or WWLB (an inverse of WWL) depending on whether Transistor 101 is an n-type transistor or a p-type transistor. In some embodiments, the source or drain terminals of Transistor 101 is coupled to WBL while the drain or source terminal of Transistor 101 is coupled to the SN. In some embodiments, the SN is coupled to read port circuitry 104.

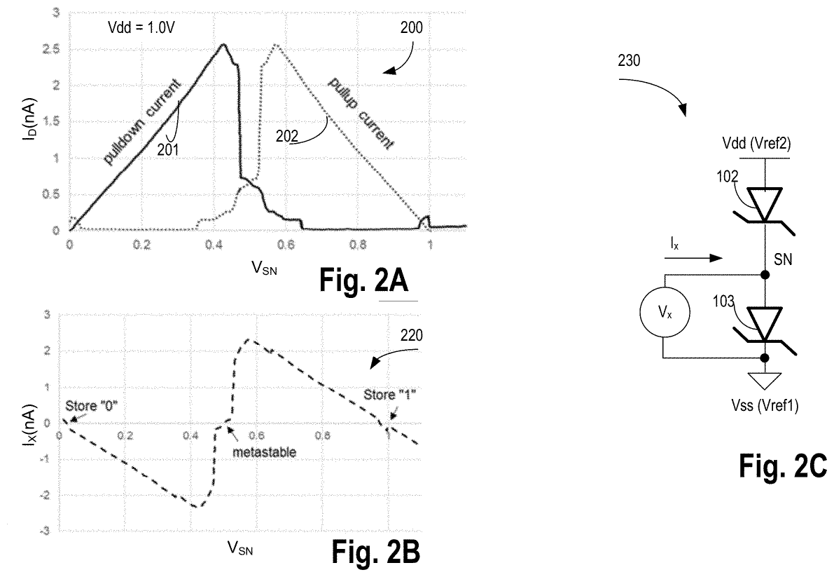

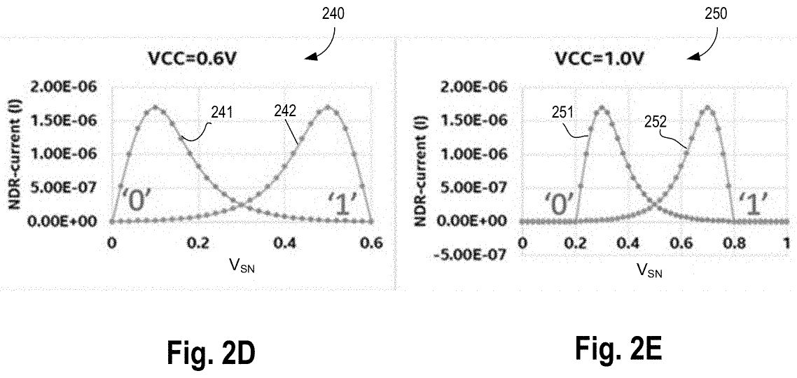

The twin cell (e.g., first and second NDR devices 102 and 103) helps to hold memory state on SN. Current driving capability of NDR twin is low (as shown in FIGS. 2A-B), but sufficient to overcome leakage that gradually drains charge through transistors coupled to the storage node SN. For example, some leakage is gate leakage through transistor MN2, while some leakage is through source or drain terminals of transistor MN1. In some embodiments, current from NDR device (e.g., one of NDR devices 102 or 103) mitigates the loss of charge from leakage on SN and can restore the stored charge on SN to the original value.

In various embodiments, reference is made to a baseline NDR-SRAM. Baseline NDR-SRAM cell works on the principle of hysteretic feedback of two series connected NDR devices. In the baseline NDR-SRAM, the devices are traditional CMOS devices and the diodes are Esaki diodes. The nature of the CMOS process requires that all devices are fabricated on the FOEL of the die. As such, higher level layers (e.g., layers in the BOEL) remain reserved for routing purposes only. The NDR-SRAM of various embodiments are fabricated in the BOEL of the die resulting in higher density than traditional NDR-SRAM.

When biased at ‘0’ or ‘1’, NDR-SRAM retains the state (RET) as long as circuit is not disturbed by peripheral circuits. In order to write (WR) a new value into the SRAM cell, internal feedback is overcome with the help of peripheral circuits. In addition to conditions for successful WR and RET, during a read operation (RD), it should be ensured that the internal feedback is not disturbed. The use of separate RD and WR port significantly reduce RD disturbance of this cell as compared to traditional 6T SRAM cell. Due to process-variation inherent in scaled technologies, RD/WR/RET failures are inevitable. Unlike SRAMs where retention failure can be improved by increasing power-supply, in NDR-SRAM due to fixed NDR characteristics which are independent of voltage, retention failures cannot improved. For example, increasing VCC does not change the “0” and “1” stable points of the cell. Hence, various embodiments use Schmitt-Trigger based NDR-SRAM to improve the feedback strength.

FIGS. 2A-C illustrate plots 200 and 220, respectively, and associated circuit 230, respectively, showing I-V characteristics of an NDR diode. For FIG. 2A, the x-axis is voltage in volts on SN (i.e., V_{SN}), and the y-axis is current in nA through the NDR device (e.g., 102 and 103). For FIG. 2B, the x-axis is voltage on in volts on SN (i.e., V_{SN}), and the y-axis is current Iₓ in nA into the storage node SN. Plots 200 and 220 are formed using circuit 230 of FIG. 2C, in which NDR devices 102 and 103 are replaced with Esaki diodes. Here, Vref2 is Vdd (power supply) while Vref1 is ground (Vss), and voltage source Vx is used to drive or sink current to or from the storage node SN.

Referring back to FIG. 2A, when V_{SN} increases from 0 V, pull down current 201 (e.g., current from SN to ground through NDR device 103) increases while the pull up current 202 (e.g., current from SN to Vdd through NDR device 102) remains zero or close to zero until near 0.5 V V_{SN}. Near 0.5 V on the storage node SN, pull down current 201 suddenly falls close to zero while pull up current 202 suddenly rises. As V_{SN} further increases, pull up current 202 declines and reaches near zero as V_{SN} approaches near equal to Vdd, while the pull down current 201 remains substantially near to zero and equal to current 202. The region near V_{SN} of 0.5 V is a meta-stable region as shown in FIG. 2B.

When the storage node SN is storing ‘0’, device 103 remains in high gain region so that any disturbance to the storage node SN (e.g., Vss+Δ or Vref1+Δ) will be compensated by higher pull-down current. Similarly, when the storage node SN is storing ‘1’, device 102 remains in high gain region and compensates for any fluctuation from “Vdd” to Vdd−Δ (or from Vref2 to Vref2−Δ). This ensures that values are retained actively.

In FIG. 2B, plot 220 shows the current Iₓ when SN stores a ‘0’ and when SN stores a ‘1’. When V_{SN} is at a high voltage, first NDR device 102 sources current more strongly than the second NDR device 103 can sink it, thus keeping the voltage on SN high. Conversely, when V_{SN} is at a low voltage, pull-down NDR device 103 sinks current more strongly and the voltage on the storage node SN can be held at a low voltage.

FIGS. 2D-E illustrates plots 240 and 250, respectively, showing I-V characteristics for different power supply voltages, in accordance with some embodiments. Plot 240 shows data 241 and 242 are stored by two NDR devices with positive feedback when power supply Vcc=0.6V. Plot 250 shows data 251 and 252 are stored by two NDR devices with positive feedback when power supply is increased to Vcc=1.0V. Note that since I-V characteristics are fixed for the NDR devices, increasing Vcc will result moving ‘logic 0’ from 0V to 0.2V and moving ‘logic 1’ from 0.6V to 0.8V, for example.

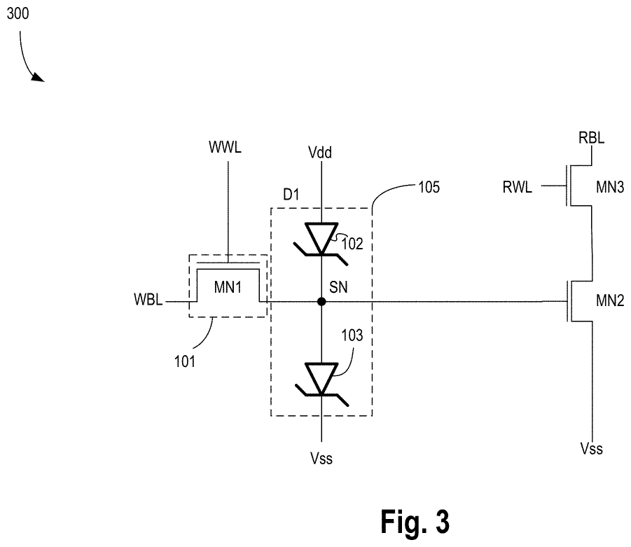

FIG. 3 illustrates a schematic of an NDR memory cell 300 with separate read and write ports, in accordance with some embodiments of the disclosure. While various embodiments here are described with reference to n-type BEOL transistors, p-type BEOL transistors may also be used. In some embodiments, a combination of p-type and n-type BEOL transistors may be used for the various embodiments described here. In this example, the access transistor 101 is an n-type BEOL transistor MN1, first and second NDR devices 102 and 103 together provide Schmitt Trigger behavior, and read port circuitry 103 comprises n-type BEOL transistors MN2 and MN3. In some embodiments, the cathode of Schmitt Trigger based diode D1 (first NDR device 102) is coupled to storage node SN while the anode of Schmitt Trigger based diode D1 is coupled to Vdd (an example of Vref2). In some embodiments, the anode of Schmitt Trigger based diode D2 (second NDR device 103) is coupled to the storage node SN while the cathode of Schmitt Trigger based diode D2 is coupled to Vss (an example of Vref1).

In some embodiments, the gate terminal of BEOL transistor MN2 is coupled to the storage node SN, the source of BEOL transistor MN2 is coupled to Vss (an example of Vref1), and the drain of BEOL transistor MN2 is coupled to BEOL transistor MN3. In some embodiments, the source terminal of BEOL transistor MN3 is coupled to BEOL transistor MN2. In some embodiments, the drain terminal of BEOL transistor MN3 is coupled to the read bit-line (RBL). In some embodiments, the gate terminal of BEOL transistor MN3 is coupled to the read word-line (RWL).

The memory cell here operates similarly to an 8-T SRAM cell, where there are separate read/write ports. For the reading, current differences can be used to detect a “0” or “1”. For example, RBL is pre-charged to a value before the read, and depending if the storage node is “0” or “1”, the node will be left alone or start to discharge to lower value. In some embodiments, to write data to the memory cell, RWL is de-activated (e.g., turned to logic low to turn off transistor MN3), and access transistor MN1 is turned on (e.g., WWL is set to logic high), and data on WBL is transferred to SN. In various embodiments, first and second NDR devices 102 and 103 assist with holding the data on the storage node SN using Schmitt triggered feedback mechanism.

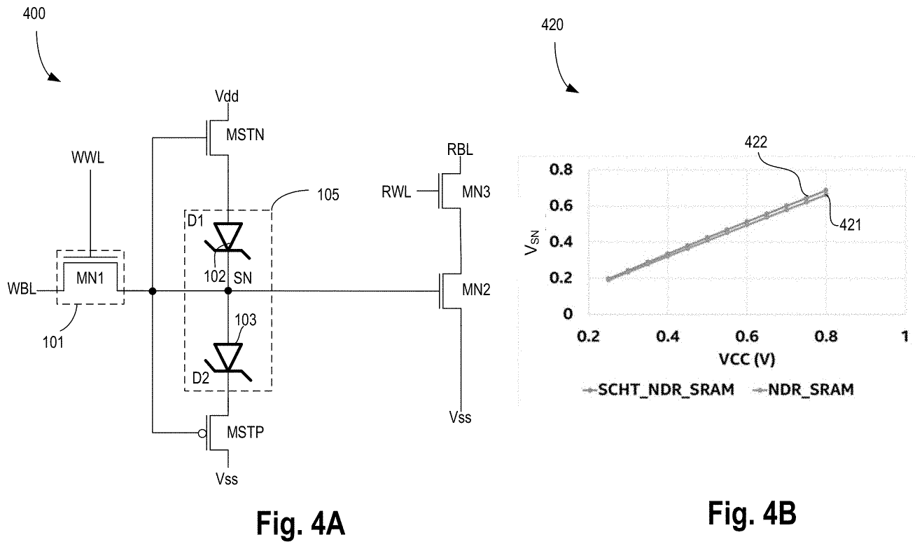

FIG. 4A illustrates a schematic of an NDR memory cell 400 with five transistors, in accordance with some embodiments. In some embodiments, the feedback provided by Schmitt trigger NDR devices of FIG. 1 and FIG. 3 can be made stronger by incorporating two additional devices in series with the Schmitt trigger based NDR devices. This updated stronger Schmitt trigger structure can be used for improving read operation and for also improving retention V_{MIN}, which is the minimum supply voltage for an operational memory device. Here, the two additional devices are n-type transistor MSTN and p-type transistor MSTP.

In some embodiments, the n-type transistor MSTN is coupled in series with NDR device 102 and also coupled to Vdd. In some embodiments, the p-type transistor MSTP is coupled in series with NDR device 103 and also coupled to Vss. In some embodiments, the gate terminals of the n-type transistor MSTN and the p-type transistor MSTP are coupled together and also coupled to the storage node SN. In some embodiments, the two additional transistors MSTN and MSTP self-cut the leakage from the NDR devices 102 and 103, by means of a Schmitt Trigger action, thus improving RET operation. In some embodiments, the Schmitt trigger action is provided by the two additional transistors MSTN and MSTP which can be realized using conventional transistors in front-end-of-line (FEOL) or IGZO transistors in backend of line (BEOL) depending on the implementation.

FIG. 4B illustrates plot 420 showing improvement in data retention by the NDR memory of FIG. 4A relative to a typical NDR memory, in accordance with some embodiments of the disclosure. Here, x-axis is supply voltage and y-axis is the voltage on the storage node SN. Curve 421 is the data for the baseline NDR-SRAM while curve 422 is the data for the NDR memory of FIG. 4A. Plot 420 shows the comparison between baseline NDR-SRAM cell and the Schmitt Trigger based NDR-SRAM cell of FIG. 4A in terms of potential at the storage node SN while storing logic 1. The improvement in the storage node SN voltage V_{SN} is approximately 4% at 0.8 V, in this example, as shown by the curves 421 and 422. While the results shown are at typical process at 25 Celsius (C), more improvement is expected at fast process and high temperature conditions, for example.

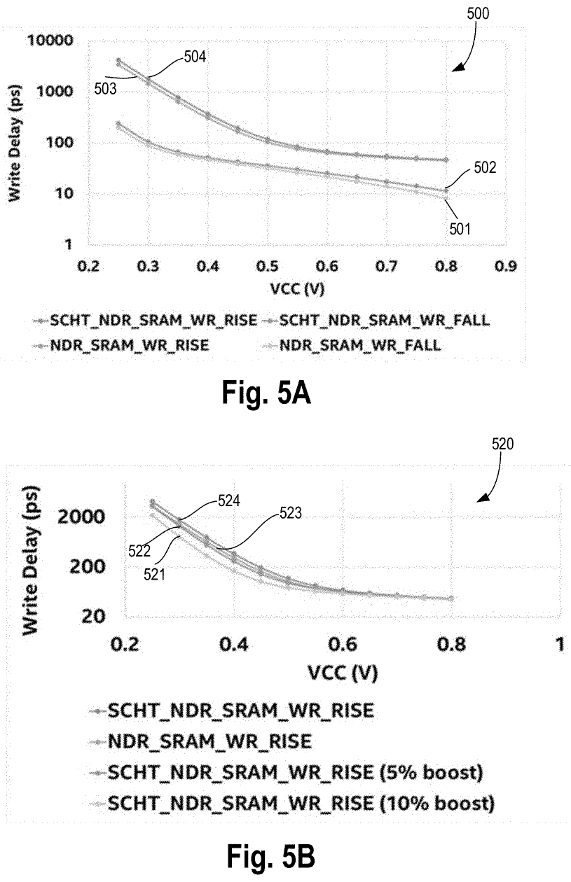

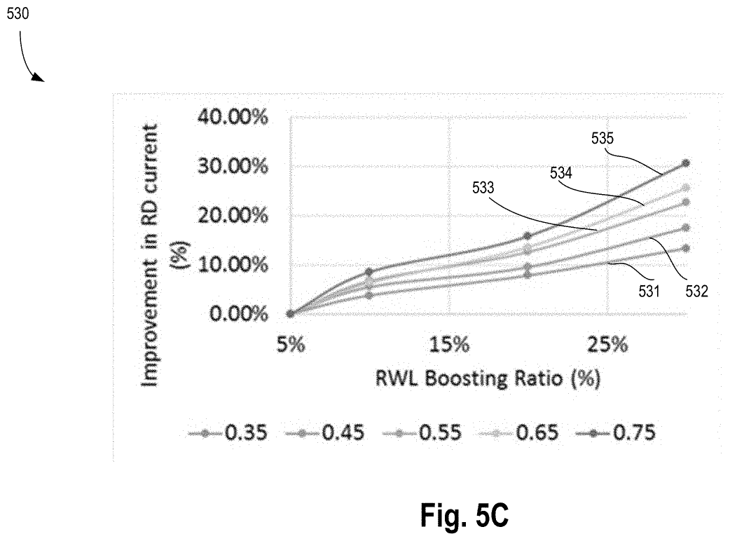

FIG. 5A illustrates plot 500 showing rise and fall write delays of the NDR memory relative to a typical NDR memory, in accordance with some embodiments. Here, x-axis is supply voltage and the y-axis is the write delay in picoseconds (ps). Due to the stronger Schmitt-trigger action of the NDR-SRAM cell of some embodiments, writeability of the cell slightly degrades as shown in FIG. 5A which compares rise and fall write delays of NDR-SRAM cell of some embodiments to the baseline cell. Here, curve 501 illustrates fall write delay across power supplies for the baseline NDR memory, curve 502 illustrates fall write delay across power supplies for the stronger Schmitt Trigger based NDR memory, curve 503 illustrates rise write delay across power supplies for the baseline NDR memory, and curve 504 illustrates rise write delay across power supplies for the stronger Schmitt Trigger based NDR memory. In order to improve WR speed, Write WL (WWL) boosting is performed, in accordance with some embodiments.

FIG. 5B illustrates plot 520 showing the effect of write word-line (WWL) boosting for the NDR memory compared to a typical NDR memory, in accordance with some embodiments. Here, x-axis is supply voltage and the y-axis is the write delay in picoseconds (ps). With only 5% and 10% boosting WWL (rise) improves write delay by 5.9% and 13.6%, respectively. Here, the term boosting refers to increasing voltage on a line. In this example, with merely 5% WWL boosting, write delay is slightly better than baseline NDR-SRAM. Similar improvement in write-time is achieved with writing ‘0’ as well. Here, curve 521 shows rise write delay for the Schmitt Trigger based NDR memory with 10% WWL boosting, curve 522 shows rise write delay for the Schmitt Trigger based NDR memory with 5% WWL boosting, curve 523 shows rise write delay for the baseline NDR memory with no WWL boosting, and curve 524 shows rise write delay for the Schmitt Trigger based NDR memory with no WWL boosting.

FIG. 5C illustrates plot 530 showing improvement in read current with read word-line (RWL) boasting, in accordance with some embodiments. Here, curves 531, 532, 533, 534, and 535 show RWL boosting by 0.35 V, 0.45 V, 0.55 V, 0.65 V, and 0.75 V, respectively. The stronger Schmitt Trigger based NDR-SRAM (e.g., of FIG. 4A) improves RD performance by increasing logic “1” voltage at the storage node thus increasing the BL discharge current (for reading “1”) in the RD port. Further improvement in RD performance is observed by boosting RWL. FIG. 5C shows the improvement in ΔI (RD-current ‘1’−RD-current ‘0’) with RWL boosting.

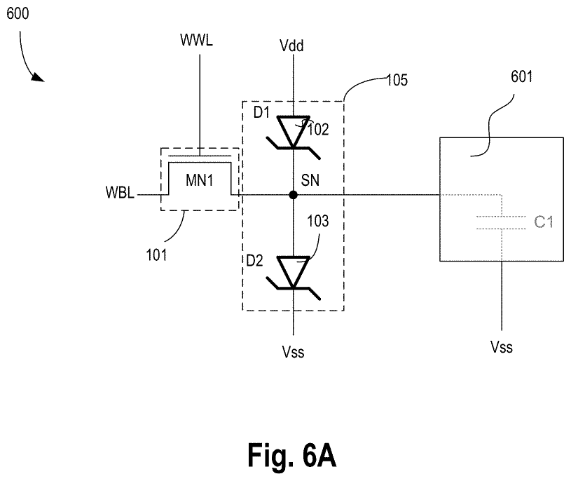

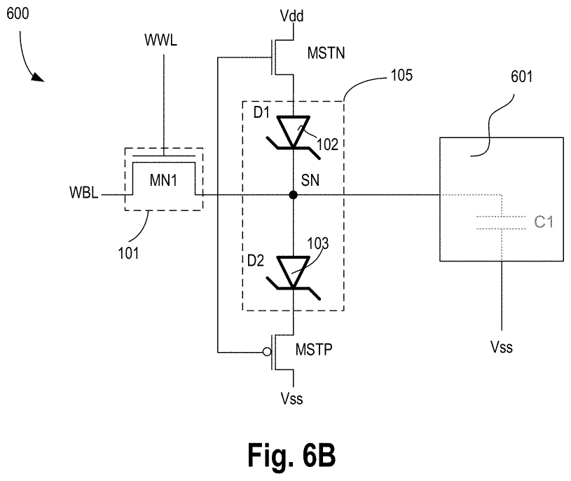

FIG. 6A illustrates schematic 600 of an NDR memory cell with one transistor and a field programmable grid array (FPGA), in accordance with some embodiments of the disclosure. In some embodiments, read port 104 is implemented using Field Programmable Grid Array (FPGA) 601. In some embodiments, FPGA 601 comprises one or programmable pass-gates. In some embodiments, transistor MN1 and programmable pass-gates 601 are formed on the BEOL of the die along with NDR devices 102/103. In some embodiments, transistor MN1 and programmable pass-gates 601 are formed using TFTs. In some embodiments, the read port 104 comprises a capacitor 104. In some embodiments, to further increase the density, IGZO can be used for fabricating FPGA based SRAM cell. Since an IGZO device offers very low leakage (e.g., less than 0.1 pA), storage node SN will be held stable while storing ‘1’ during retention mode (assuming BL is grounded during idle time).

However, by removing separate read port, the cell becomes susceptible to flipping during a read operation, which can be compensated by adding a 3D capacitor C1 to store charge. Since this cell is actively supplied with leakage current from VCC, refresh may not be used. Due to absence to RWL and RBL, WWL is used to improve the write operation by WWL boosting as well as to improve the retention by WWL-under drive and by the use 3D capacitor.

FIG. 6B illustrates schematic 620 of an NDR memory cell with one transistor and a field programmable grid array (FPGA), in accordance with some embodiments of the disclosure. Compared to FIG. 6A, here additional two transistors MSTN and MSTP are added in series with NDR devices 105 to improve the Schmitt trigger mechanism and to also improve retention and read performance. Schematic 620 is also similar to schematic 400 except that the read port 105 is generalized as being implemented in an FPGA, and may also include a capacitor C1 coupled to Vss (ground).

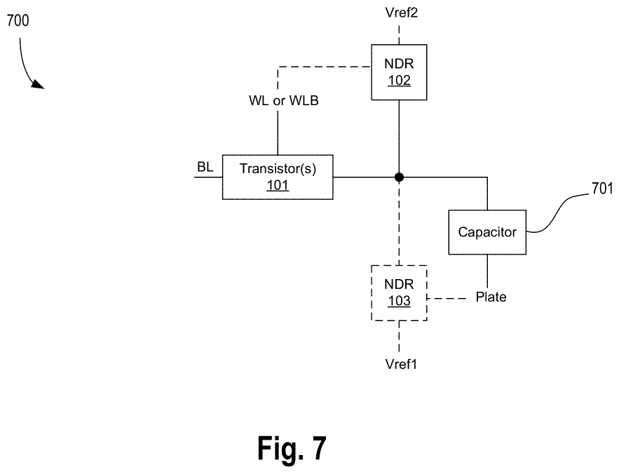

FIG. 7 illustrates schematic 700 of a Schmitt Trigger based NDR memory cell with one transistor and capacitor, in accordance with some embodiments of the disclosure. In some embodiments, the storage node SN is coupled to capacitor 701 such that a first terminal of capacitor 701 is coupled to the storage node SN and a second terminal of capacitor 701 is coupled to Plate.

In some embodiments, Capacitor 701 is a metal capacitor formed above the substrate. For example, capacitor 701 is also formed on the BEOL of the die. In one embodiment, Capacitor C1 701 is a TFT based capacitor formed by a transistor in the BEOL. In some embodiments, Capacitor C1 701 is a hybrid capacitor formed from TFT transistor(s) in the BEOL and a metal mesh.

In some embodiments, the voltage on the Plate is Vdd/2 (e.g., half of the power supply voltage). In other embodiments, the Plate can be biased at different voltage levels. The twin cell (i.e., NDR devices 102 and 103) helps to hold memory state on capacitive SN. Current driving capability of NDR twin is low, but sufficient to overcome leakage that gradually drains charge off Capacitor 701. In some embodiments, the current from NDR device (i.e., one of NDR devices 102 or 103) mitigates the loss of charge from leakage on SN and can restore the stored charge on SN to the original value.

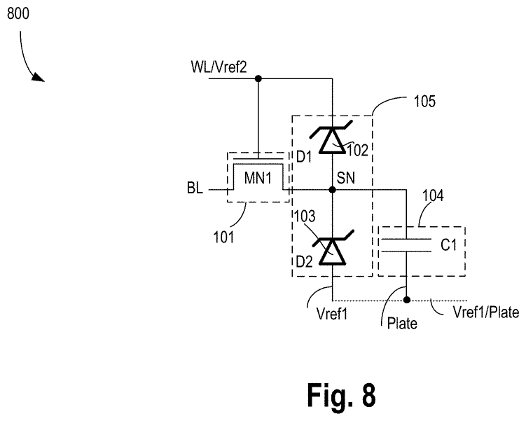

FIG. 8 illustrates a schematic of a Schmitt Trigger based NDR memory cell 800 with one transistor and capacitor, in accordance with some embodiments of the disclosure. In some embodiments, one or more transistors 101 are illustrated by one or more n-type BEOL transistors (MN1) 101, NDR device 102 is illustrated by a Schmitt Trigger based diode D1, and NDR device 103 is illustrated by another Schmitt Trigger based diode D2. In some embodiments, Capacitor C1 104 (e.g., capacitor 701) is a metal capacitor formed above the substrate. For example, capacitor 104 is also formed on the BEOL of the die. In one embodiment, Capacitor C1 104 is a TFT based capacitor formed by a transistor in the BEOL. In some embodiments, Capacitor C1 104 is a hybrid capacitor formed from TFT transistor(s) in the BEOL and a metal mesh. In some embodiments, one of the terminals (here, the cathode) of D1 is coupled to WL or Vref2 such that the same metal line is used for controlling the gate terminal of MN1. One technical effect of such an embodiment is that the number of interconnect routings in the bit-cell is reduced, which frees up area for other interconnect routings.

In this embodiment, WL and/or the capacitor back Plate signal is reused to supply the NDR twin (i.e., NDR devices 102 and 103). In such an embodiment, additional routings of Vdd (power supply) and Vss (ground) to each bit-cell is reduced because they are no longer used by bit-cell 800. By reducing the metal routes, size of the bit-cell, and thus the memory array, is reduced because metal routing space, and additional contacts and vias for providing Vdd and Vss are reduced. In some embodiments, since WL is generally at a zero or negative bias, it is used to substitute for ground. While the NDR twin may cease to hold state when WL is asserted, this is not problematic because WL assertion occurs transiently when bit-cell 300 is read/written and the charge on SN is restored to the full value at that time. Switching the WL may introduce parasitic currents that discharge Capacitor 104 and parasitic capacitors, but these currents are small compared to those of access transistor MN1. In some embodiments, the positive supply of the NDR twin may be connected to the back Plate of Capacitor 104 when the Plate is held at a logic-1 voltage.

In some embodiments, the NDR supply voltage is combined with an addressing line (e.g., word-line, bit-line) or a plate line (i.e., Plate) because the latching behavior from the NDR device is needed to overcome leakage. In some embodiments, while the NDR device may cease to form a latching element when the addressing lines are used, memory state may be maintained dynamically. At this time in the operation, the low current of the NDR devices is beneficial by preventing a read disturb (e.g., bit-cell erasure).

Some non-limiting technical effects of bit-cell 300 are that using NDR devices 102 and 103 in conjunction with storage Capacitor 104, eliminates the need for refresh operations, which saves energy and increases memory array bandwidth. Additionally, the leakage-canceling NDR device enables further scaling of bit-cell 300. For example, Capacitor 104 can be made smaller or leakier without hurting worst-case read margins. Additionally, it is possible to budget for increased leakage through the access transistor MN1. This enables device scaling or the elimination of tightly regulated WL over-/under-drive voltages.

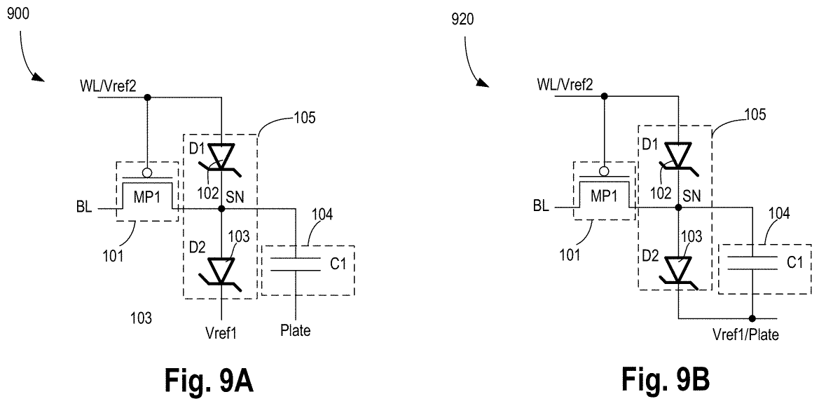

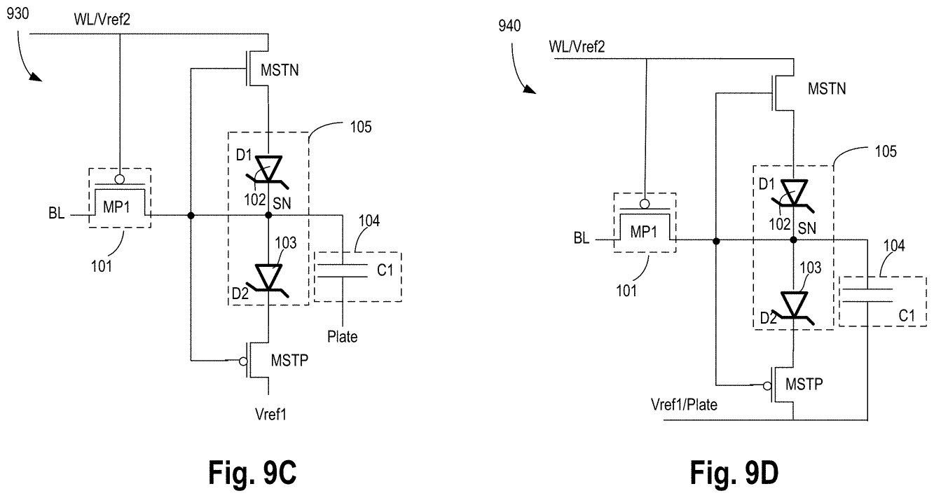

FIGS. 9A-D illustrate multiple embodiments of single NDR device based memory bit-cells 900, 920, 930, and 940, respectively, with p-type transistors and a capacitor, according to one embodiment of the disclosure. So as not to obscure the embodiments of FIGS. 9A-D, differences between the embodiments of FIG. 8 and the embodiments of FIGS. 9A-D are discussed.

The embodiments of FIGS. 9A-B are similar to the embodiments of FIG. 8, but using a p-type BEOL transistor instead of an n-type BEOL transistor. Functionally, bit-cells 900 and 920 operate similarly to bit-cell 800. In these embodiments, the coupling of the terminals of NDR devices D1 and D2 are also reversed. For example, in the embodiment of bit-cell 900, the anode of Schmitt Trigger based NDR device D1 is coupled to WL or Vref2 and the cathode of NDR device D1 is coupled to the storage node SN. Likewise, the anode of Schmitt Trigger based NDR device D2 is coupled to the storage node SN and the cathode of Schmitt Trigger based NDR device D2 is coupled to Vref1 or Plate.

Here, Vref2 (which is tied to WL) is ‘1’ to turn off access device MP1, and Vref1=Vss during retention mode.

During read operation, WL=0 and in this case Vref1=Vref2=Vss. During read operation, if the storage node SN was storing ‘0’, this value is not disturbed by RD operation. However, if the node SN was storing ‘1’, then SN node may move towards Vss since both terminals Vref1 and Vref2 are Vss. However, when WL goes to 1 after reading, for example in retention operation, Vref1=Vss while Vref2=Vdd. During the retention operation, capacitor C1 ensures that 1 is restored at the storage node SN. Note that capacitor C can restore 1 if the read-operation is done quickly (e.g., less than 1 ns time scale).

During write operation, WL=0 and in this case Vref1=Vref2=Vss. In this case, writing ‘0’ is relatively easy compared to writing ‘1’ on SN. For example, BL has to write 1 overcoming competition from Vref2 and Vref1 current which will force ‘0’ to node SN. From baseline design with BL, WL, Vref1, Vref2 and capacitor back-plane connection (5 signals), the design of some embodiments as illustrated by FIGS. 9A-D can reduce signals to BL, WL, Vref2 (3 signals) thereby improving density of the memory array.

In some embodiments of FIG. 9B, further number of metal routings, contacts, and vias are reduced by coupling the cathode of the Schmitt Trigger based NDR device D2 with Vref1 or Plate. The reversal of the anode and cathode connections is done to match the value of the de-asserted word-line voltage with the value needed to bias the Schmitt Trigger based NDR devices in a voltage region where NDR characteristics occur.

The embodiments of FIGS. 9C-D are similar to the embodiments of FIGS. 9A-B except that additional feedback through transistors MSTN and MSTP are provided to enhance the strength of the Schmitt trigger mechanism.

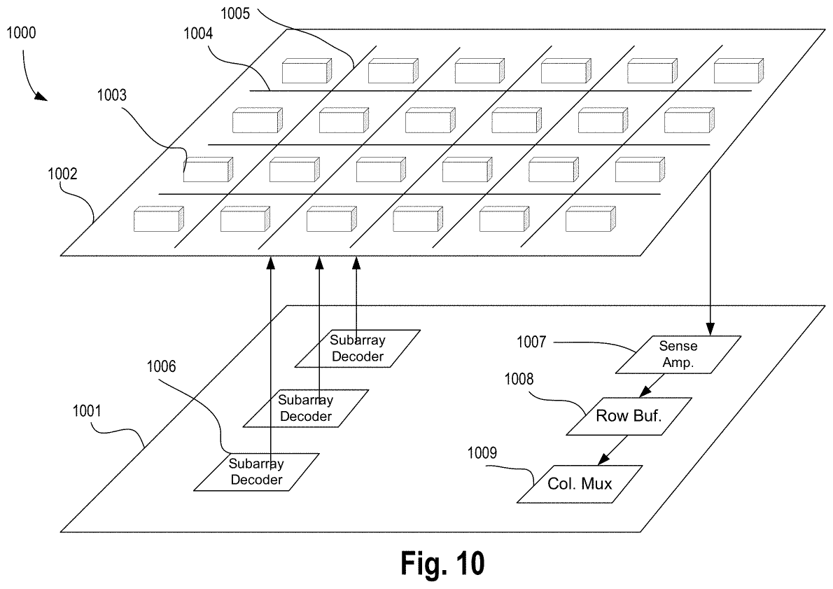

FIG. 10 illustrates a three-dimensional (3D) architecture 1000 of a Schmitt Trigger based NDR based memory, in accordance with some embodiments. In some embodiments, the peripheral circuits 1001 associated with the NDR based memory cells are formed on the FEOL of a die. In some embodiments, the peripheral circuits 1001 associated with the NDR based memory cells are also formed in the BEOL of the die. The peripheral circuits 1001 may include any circuit used to enable write and read operations to and from the NDR based memory cells. For example, peripheral circuits 1001 includes subarray decoders 1006, sense amplifier 1007, row buffers 1008, column multiplexers 1009, etc.

In some embodiments, memory density is increased by forming an array 1002 of NDR based memory cells 1003 in the BEOL of a die. The memory cells can be according to any one of the memory cell architectures described with reference to the various embodiments. Here, the lines 1004 and 1005 are the WWL, RWL, WBL, etc. In some embodiments, 3D Indium gallium zinc oxide, or IGZO, devices are used to substitute Si-transistors since a 3D IGZO device can be realized in BEOL. In some embodiments, the peripheral circuits 1001 are implemented in silicon and the transistors of the peripheral circuits 1001 are coupled to the BEOL array 1002. For example, the RD/WR IO circuitry (address decoder) can be implemented using Si-transistors in FEOL and shared across array 1001. Since IO and decoder circuitries are common across multiple rows and columns as in conventional design, but with the memory cell in 3D, array efficiency is maximized with this design. Since ON current of an IGZO device is approximately O1X lower than Si-transistor, any degradation in read and write speeds, can be compensated by RWL and WWL boosting, respectively.

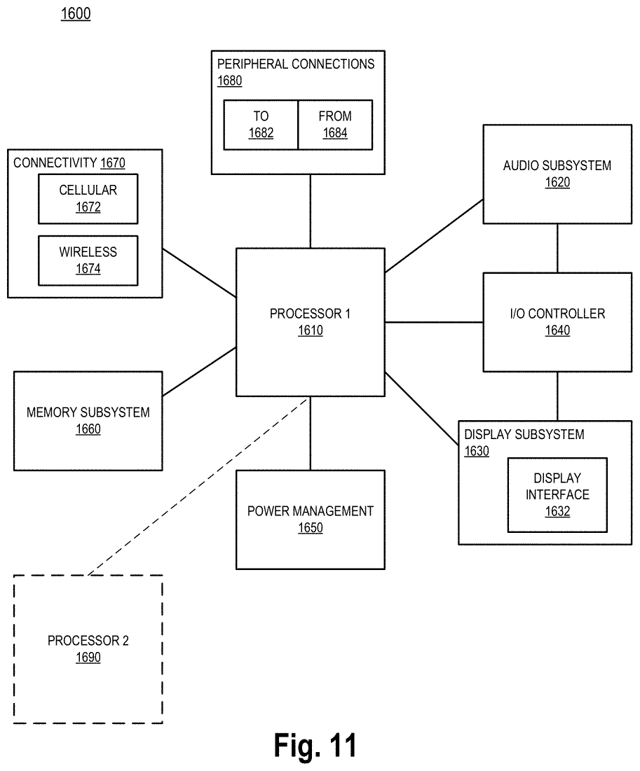

FIG. 11 is a smart device or a computer system or a SoC (System-on-Chip) with NDR device based memory, according to one embodiment of the disclosure. It is pointed out that those elements of FIG. 11 having the same reference numbers (or names) as the elements of any other figure can operate or function in any manner similar to that described, but are not limited to such.

FIG. 11 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 with NDR device based memory, according to the embodiments discussed. Other blocks of the computing device 1600 may also include the apparatus of NDR device based memory of the embodiments. The various embodiments of the present disclosure may also comprise a network interface within 1670 such as a wireless interface so that a system embodiment may be incorporated into a wireless device, for example, cell phone or personal digital assistant.

In one embodiment, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600. In some embodiments, Memory subsystem 1660 comprises Schmitt Trigger based NDR memory as discussed in various embodiments.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

### Example 1

An apparatus comprising: a storage node; a first device coupled to the storage node; a second device coupled to a first reference and the storage node, wherein the second device has negative differential resistance (NDR); a third device coupled to a second reference and the storage node, wherein the third device has NDR; and a circuitry for reading data, the circuitry coupled to the storage node and the first, second, and third devices, wherein the first, second, and third devices, and the circuitry are positioned in a backend-of-line (BEOL) of a die.

### Example 2

The apparatus of example 1, wherein the circuitry comprises a fourth device having a gate terminal coupled to the storage node, and a source terminal coupled to the second reference.

### Example 3

The apparatus of example 2, wherein the circuitry comprises a fifth device having a gate terminal coupled to a read word-line (RWL), a source/drain terminal coupled to a read bit-line (RBL), and a drain/source terminal coupled to the fourth device.

### Example 4

The apparatus of example 1, wherein the first reference is a power supply node while the second reference is a ground supply node.

### Example 5

The apparatus of example 1, wherein the second and third devices comprise Schmitt triggered devices.

### Example 6

The apparatus of example 1, wherein the first device has a gate terminal coupled to a write word-line (WWL).

### Example 7

The apparatus of example 1, wherein the first device is coupled to a write bit-line (WBL).

### Example 8

The apparatus of example 1, wherein the first device is one of: a p-type transistor or an n-type transistor.

### Example 9

The apparatus of example 1, wherein the first device comprises Indium, Gallium, Zinc, and Oxygen.

### Example 10

An apparatus comprising: a storage node; a first device coupled to the storage node; a second device coupled to the storage node, wherein the second device has negative differential resistance (NDR); a third device coupled to the storage node, wherein the third device has NDR; a fourth device of first conductivity type coupled in series with the second device and coupled to a first reference; a fifth device of second conductivity type coupled in series with the third device and coupled to a second reference, wherein gate terminals of the fourth and fifth devices are coupled together and coupled to the storage node; and a circuitry for reading data, the circuitry coupled to the storage node and the first, second, and third devices.

### Example 11

The apparatus of example 10, wherein the first, second, third, fourth, and fifth devices, and the circuitry are positioned in a backend-of-line (BEOL) of a die.

### Example 12

The apparatus of example 10, wherein the first, fourth, and fifth devices comprise Indium, Gallium, Zinc, and Oxygen.

### Example 13

The apparatus of example 10, wherein the second and third devices comprise Schmitt triggered devices.

### Example 14

The apparatus of example 10, wherein the first device has a gate terminal coupled to a write word-line (WWL), and wherein the first device is also coupled to a write bit-line (WBL).

### Example 15

The apparatus of example 10, wherein the circuitry comprises: a sixth device having a gate terminal coupled to the storage node, and a source terminal coupled to the second reference; and a seventh device having a gate terminal coupled to a read word-line (RWL), a source or drain terminal coupled to a read bit-line (RBL), and a drain or source terminal coupled to the sixth device.

### Example 16

A system comprising: a processor; a memory coupled to the processor, wherein the memory comprises: an array of memory bit-cells positioned in a backend-of-line (BEOL) of a die; a sense amplifier positioned in a frontend-of-line (FEOL) of the die, wherein the sense amplifier is coupled to the array of memory bit-cells, wherein a memory bit-cell of the array includes: a storage node; a first device coupled to the storage node; a second device coupled to a first reference and the storage node, wherein the second device has negative differential resistance (NDR); a third device coupled to a second reference and the storage node, wherein the third device has NDR; and a circuitry for reading data, the circuitry coupled to the storage node and the first, second, and third devices; and a wireless device to allow the processor to communicate with another device.

### Example 17

The system of example 16, wherein the second and third devices comprise Schmitt triggered devices.

### Example 18

The system of example 16, wherein the first device has a gate terminal coupled to a write word-line (WWL), and wherein the first device is coupled to a write bit-line (WBL).

### Example 19

The system of example 16, wherein the first device comprises Indium, Gallium, Zinc, and Oxygen.

### Example 20

The system of example 16, wherein the circuitry comprises: a fourth device having a gate terminal coupled to the storage node, and a source terminal coupled to the second reference; and a fifth device having a gate terminal coupled to a read word-line (RWL), a source/drain terminal coupled to a read bit-line (RBL), and a drain/source terminal coupled to the fourth device.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a storage node;
a first device coupled to the storage node;
a second device coupled to a first reference and the storage node, wherein the second device has negative differential resistance (NDR);
a third device coupled to a second reference and the storage node, wherein the third device has NDR; and
a circuitry for reading data, the circuitry coupled to the storage node and the first, second, and third devices,
wherein the first, second, and third devices, and the circuitry are positioned in a backend-of-line (BEOL) of a die.

2. The apparatus of claim 1, wherein the circuitry comprises a fourth device having a gate terminal coupled to the storage node, and a source terminal coupled to the second reference.

3. The apparatus of claim 2, wherein the circuitry comprises a fifth device having a gate terminal coupled to a read word-line (RWL), a source/drain terminal coupled to a read bit-line (RBL), and a drain/source terminal coupled to the fourth device.

4. The apparatus of claim 1, wherein the first reference is a power supply node while the second reference is a ground supply node.

5. The apparatus of claim 1, wherein the second and third devices comprise Schmitt triggered devices.

6. The apparatus of claim 1, wherein the first device has a gate terminal coupled to a write word-line (WWL).

7. The apparatus of claim 1, wherein the first device is coupled to a write bit-line (WBL).

8. The apparatus of claim 1, wherein the first device is one of: a p-type transistor or an n-type transistor.

9. The apparatus of claim 1, wherein the first device comprises Indium, Gallium, Zinc, and Oxygen.

10. An apparatus comprising:
a storage node;
a first device coupled to the storage node;
a second device coupled to the storage node, wherein the second device has negative differential resistance (NDR);
a third device coupled to the storage node, wherein the third device has NDR;
a fourth device of first conductivity type coupled in series with the second device and coupled to a first reference;
a fifth device of second conductivity type coupled in series with the third device and coupled to a second reference, wherein the first conductivity type is different from the second conductivity type, and wherein gate terminals of the fourth and fifth devices are coupled together and coupled to the storage node; and
a circuitry for reading data, the circuitry coupled to the storage node and the first, second, and third devices.

11. The apparatus of claim 10, wherein the first, second, third, fourth, and fifth devices, and the circuitry are positioned in a backend-of-line (BEOL) of a die.

12. The apparatus of claim 10, wherein the first, fourth, and fifth devices comprise Indium, Gallium, Zinc, and Oxygen.

13. The apparatus of claim 10, wherein the first conductivity type is an n-type conductivity, and wherein the second conductivity type is a p-type conductivity.

14. The apparatus of claim 10, wherein the first device has a gate terminal coupled to a write word-line (WWL), and wherein the first device is also coupled to a write bit-line (WBL).

15. The apparatus of claim 10, wherein the circuitry comprises:
a sixth device having a gate terminal coupled to the storage node, and a source terminal coupled to the second reference; and
a seventh device having a gate terminal coupled to a read word-line (RWL), a source or drain terminal coupled to a read bit-line (RBL), and a drain or source terminal coupled to the sixth device.

16. A system comprising:
a processor;
a memory coupled to the processor, wherein the memory comprises:
an array of memory bit-cells positioned in a backend-of-line (BEOL) of a die;
a sense amplifier positioned in a frontend-of-line (FEOL) of the die, wherein the sense amplifier is coupled to the array of memory bit-cells, wherein a memory bit-cell of the array includes:
a storage node;
a first device coupled to the storage node;
a second device coupled to a first reference and the storage node, wherein the second device has negative differential resistance (NDR);
a third device coupled to a second reference and the storage node, wherein the third device has NDR; and
a circuitry for reading data, the circuitry coupled to the storage node and the first, second, and third devices; and
a wireless device to allow the processor to communicate with another device.

17. The system of claim 16, wherein the second and third devices comprise Schmitt triggered devices.

18. The system of claim 16, wherein the first device has a gate terminal coupled to a write word-line (WWL), and wherein the first device is coupled to a write bit-line (WBL).

19. The system of claim 16, wherein the first device comprises Indium, Gallium, Zinc, and Oxygen.

20. The system of claim 16, wherein the circuitry comprises:
a fourth device having a gate terminal coupled to the storage node, and a source terminal coupled to the second reference; and
a fifth device having a gate terminal coupled to a read word-line (RWL), a source/drain terminal coupled to a read bit-line (RBL), and a drain/source terminal coupled to the fourth device.
